(19) United States
(12) Patent Application Publication
(10) Pub. No.: US 2025/0253612 A1
(43) Pub. Date: Aug. 7, 2025

(54) HIGH POWER LASER ASSEMBLY WITH BEAM COMBINING, MULTIPLE LEVELS AND FIBER COUPLING

(71) Applicant: Daylight Solutions, Inc., San Diego, CA (US)

(72) Inventors: Alexander Jason Whitmore, San Diego, CA (US); Marcus Lanovaz, San Diego, CA (US); Francisco Javier Santos, Chula Vista, CA (US); Sara M. Campaign, San Diego, CA (US); Michael Pushkarsky, San Diego, CA (US)

(21) Appl. No.: 18/702,305

(22) PCT Filed: Oct. 20, 2022
(86) PCT No.: PCT/US2022/047281

§ 371 Date: Apr. 17, 2024

Related U.S. Application Data
(60) Provisional application No. 63/257,680, filed on Oct. 20, 2021.

(51) Int. Cl. H01S 5/0239; H01S 5/40

(52) U.S. Cl. CPC H01S 5/0239; H01S 5/4012

(57) ABSTRACT

A laser assembly (10) includes: (i) a first laser subassembly (16) that includes a first laser (26a) that generates a first laser beam (26b); a second laser (26f) that generates a second laser beam (26g); and a first beam combiner (26j) that combines the first laser beam (26b) and the second laser beam (26g) to form a first subassembly beam (16A) that is directed along a first subassembly beam axis (16B); (ii) a second laser subassembly (18) that includes a third laser (28a) that generates a third laser beam (28b); a fourth laser (28f) that generates a fourth laser beam (28g); and a second beam combiner (28j) that combines the third laser beam (28b) and the fourth laser beam (28g) to form a second subassembly beam (18A) that is directed along a second subassembly beam axis (18B) that is substantially parallel to the first subassembly beam axis (16B); and an optical assembly (22) that compresses the subassembly beams (16A) (18A) to provide the output beam (12).

### RELATED APPLICATION

This application claims priority on U.S. Provisional Application No. 63/257,680 filed on Oct. 20, 2021, and entitled “HIGH POWER LASER ASSEMBLY WITH BEAM COMBINING, MULTIPLE LEVELS AND FIBER COUPLING”. As far as permitted, the contents of U.S. Provisional Application No. 63/257,680 are incorporated herein.

### BACKGROUND

Laser assemblies are used in many applications, such as medical applications, scientific applications, test labs, cutting lasers, and welding lasers. In many applications, important requirements of the laser assembly include maximizing output power, and minimizing the form factor. There is a never-ending desire to increase the power output, while decreasing the form factor for the laser assembly.

### SUMMARY

The present invention is directed to a laser assembly for generating an output beam. In one implementation, the laser assembly includes: (i) a first laser subassembly that includes a first laser that generates a first laser beam; a second laser that generates a second laser beam; and a first beam combiner that combines the first laser beam and the second laser beam to form a first subassembly beam that is directed along a first subassembly beam axis; (ii) a second laser subassembly that includes a third laser that generates a third laser beam; a fourth laser that generates a fourth laser beam; and a second beam combiner that combines the third laser beam and the fourth laser beam to form a second subassembly beam that is directed along a second subassembly beam axis that is substantially parallel to the first subassembly beam axis; and (iii) an optical assembly that compresses the subassembly beams to provide the output beam.

As an overview, with this design, the laser assembly can have relatively high power, while being optically and mechanically stable during temperature cycles and mechanical vibrations.

In any of the implementations, one or more of the beam combiners can be a polarization beam combiner.

In any of the implementations, one or each laser is an ultra-violet emitter that directly generates a laser beam having a center wavelength in the ultra-violet wavelength range. As used herein, the ultra-violet wavelength range (“UV range”) shall include wavelengths of one hundred to four hundred and ten nanometers (100-410 nm). In one non-exclusive implementation, each laser can directly generate a laser beam having a center wavelength in the 370-380 nanometer range. In another one non-exclusive implementation, each laser can directly generate a laser beam having a center wavelength in the 400-410 nanometer range.

In certain implementations, the output beam is launched into free space. In other implementations, the output beam is coupled into an optical fiber.

In any of the implementations, the laser assembly can include a third laser subassembly that generates a third subassembly beam along a third subassembly beam axis that is substantially parallel to the first subassembly beam axis and the second subassembly beam axis. In this implementation, the optical assembly compresses the subassembly beams to provide the output beam.

In one specific example, the power of the output beam is at least one watt in the ultra-violet range.

In any of the implementations, the laser assembly can include a fiber including an inlet facet, and a beam focuser that focuses the output beam at the inlet facet so that the output beam is accepted by the inlet facet. In any of the implementations, the laser assembly can include a focuser attachment assembly that allows for the adjustment of the beam focuser with at least three (e.g., three, four, five, or six) degrees of freedom relative to the optical assembly, and a fiber attachment assembly that allows for the adjustment of the inlet face with at least three (e.g., three, four, five, or six) degrees of freedom relative to the beam focuser. In a specific example, the laser assembly includes a focuser attachment assembly that allows for the adjustment of the beam focuser along three axes, and a fiber attachment assembly that allows for the adjustment of the inlet face along three axes.

In any of the implementations, the optical assembly can include a plurality of spaced apart prisms, and/or can compress the subassembly beams along an axis.

In any of the implementations, the first laser can include a first collimator that nearly collimates the first laser beam, and a first beam corrector that further collimates the first laser beam. In certain implementations, the first collimator and the first beam corrector together act similar to a single collimation lens.

In any of the implementations, the laser assembly can include (i) a mounting frame having a first frame that retains the laser subassemblies to form a first assembly level, and a second frame that retains the optical assembly to form a second assembly level; and (ii) a transfer assembly that transfers the subassembly beams from the first assembly level to the second assembly level.

In another implementation, the laser assembly comprises: (i) a first assembly level that includes a first laser subassembly that generates a first subassembly beam that is directed along a first subassembly beam axis; and a second laser subassembly that generates a second subassembly beam that is directed along a second subassembly beam axis that is substantially parallel to the first subassembly beam axis; (ii) a second assembly level that includes an optical assembly that compresses the subassembly beams to provide the output beam, wherein the second assembly level is different from the first assembly level; and (iii) a transfer assembly that transfers the subassembly beams from the laser subassemblies on the first assembly level to the optical assembly on the second assembly level.

In any of the implementations, one, two, or each laser subassembly includes at least two lasers.

In yet another implementation, the laser assembly comprises: a first laser subassembly that includes (i) a first laser that generates a first laser beam; (ii) a first collimator that partially collimates the first laser beam, (iii) a first beam corrector that fully collimates the first laser beam; (iv) a second laser that generates a second laser beam; (v) a second collimator that collimates the second laser beam, (vi) a second beam corrector that further collimates the second laser beam; and (vii) a first beam combiner that combines the first laser beam and the second laser beam to form a first subassembly beam that is directed along a first subassembly beam axis.

The laser assembly can include (i) a second laser subassembly that includes: a third laser that generates a third laser beam; a third collimator that collimates the third laser beam; a third beam corrector that further collimates the third laser beam; a fourth laser that generates a fourth laser beam; a fourth collimator that collimates the fourth laser beam; a fourth beam corrector that further collimates the fourth laser beam; and a second beam combiner that combines the third laser beam and the fourth laser beam to form a second subassembly beam that is directed along a second subassembly beam axis; and (ii) an optical assembly that compresses the subassembly beams to provide an output beam.

In another implementation, a method generating an output beam includes: (i) generating a first subassembly beam that is directed along a first subassembly beam axis with a first laser subassembly that includes: a first laser that generates a first laser beam; a second laser that generates a second laser beam; and a first polarization beam combiner that combines the first laser beam and the second laser beam to form the first subassembly beam; (ii) generating a second subassembly beam that is directed along a second subassembly beam axis with a second laser subassembly that includes a third laser that generates a third laser beam; a fourth laser that generates a fourth laser beam; and a second polarization beam combiner that combines the third laser beam and the fourth laser beam to form the second subassembly beam; and (iii) compressing the subassembly beams to provide the output beam with an optical assembly.

In yet another implementation, a method for generating an output beam comprises: (i) generates a first subassembly beam that is directed along a first subassembly beam axis with a first laser subassembly that is part of a first assembly level; (ii) generating a second subassembly beam that is directed along a second subassembly beam axis that is substantially parallel to the first subassembly beam axis with a second laser subassembly that is part of the first assembly level; (iii) compressing the subassembly beams with an optical assembly to provide the output beam, wherein the optical assembly is positioned at a second assembly level that is different from the first assembly level; and (iv) transferring the subassembly beams from the laser subassemblies on the first assembly level to the optical assembly on the second assembly level with a transfer assembly.

In still another implementation, a method for generating an output beam comprises: (i) generating a first laser beam with a first laser; (ii) collimating the first laser beam with a first collimator; (iii) further collimating the first laser beam with a first beam corrector; (iv) generating a second laser beam with a second laser; (v) collimating the second laser beam with a second collimator; (vi) further collimating the second laser beam with a second beam corrector; and (vii) combining the laser beams with a first polarization beam combiner to form a first subassembly beam that is directed along a first subassembly beam axis.

In yet another implementation, the present invention is directed to a laser assembly for generating an output beam, that includes one or more of the following features: (i) a first laser that generates a first laser beam; (ii) a second laser that generates a second laser beam; (iii) a third laser that generates a third laser beam; (iv) a fourth laser that generates a fourth laser beam; (v) a beam combiner assembly that (a) combines the first laser beam and the second laser beam to form a first subassembly beam that is directed along a first subassembly beam axis; and (b) combines the third laser beam and the fourth laser beam to form a second subassembly beam that is directed along a second subassembly beam axis that is substantially parallel to the first subassembly beam axis; (vi) an optical assembly that compresses the subassembly beams to provide the output beam; (vii) wherein at least one of the lasers includes an ultra-violet emitter, and the output beam is in the ultra-violet range; (viii) a fifth laser that generates a third subassembly beam that is directed along a third subassembly beam axis that is substantially parallel to the first subassembly beam axis and the second subassembly beam axis; and wherein the optical assembly compresses the subassembly beams to provide the output beam; (ix) wherein the power of the output beam is at least one watt; (x) a fiber including an inlet facet, and a beam focuser that focuses the output beam at the inlet facet so that the output beam is accepted by the inlet facet; (xi) a focuser attachment assembly that allows for the adjustment of the beam focuser with at least three degrees of freedom relative to the optical assembly, and a fiber attachment assembly that allows for the adjustment of the inlet face with at least three degrees of freedom relative to the beam focuser; (xii) wherein the optical assembly includes a plurality of spaced apart prisms; (xiii) wherein the optical assembly compresses the subassembly beams along an axis; (xiv) wherein the first laser includes a first collimator that collimates the first laser beam, and a first beam corrector that further collimates the first laser beam; and/or (xv) a mounting frame including a first frame that retains the lasers to form a first assembly level, and a second frame that retains the optical assembly to form a second assembly level; and a transfer assembly that transfers the subassembly beams from the first assembly level to the second assembly level.

In yet another implementation, a method generating an output beam can include one or more of the following; (i) generating a first laser beam with a first laser; (ii) generating a second laser beam with a second laser; (iii) generating a third laser beam with a third laser; (iv) generating a fourth laser beam with a fourth laser; (v) combining the first laser beam and the second laser beam with a beam combiner assembly to form a first subassembly beam that is directed along a first subassembly beam axis; (vi) combining the third laser beam and the fourth laser beam with the beam combiner assembly to form a second subassembly beam that is directed along a second subassembly beam axis that is parallel to the first subassembly beam axis; (vii) compressing the subassembly beams to provide the output beam with an optical assembly; (viii) wherein at least one of the lasers includes an ultra-violet emitter, and the output beam is in the ultra-violet range; (ix) generating a third subassembly beam with a fifth laser that is directed along a third subassembly beam axis that is substantially parallel to the first subassembly beam axis and the second subassembly beam axis; and wherein the optical assembly compresses the subassembly beams to provide the output beam; (x) wherein the power of the output beam is at least one watt; (xi) a fiber including an inlet facet, and a beam focuser that focuses the output beam at the inlet facet so that the output beam is accepted by the inlet facet; (xii) a focuser attachment assembly that allows for the adjustment of the beam focuser with at least three degrees of freedom relative to the optical assembly, and a fiber attachment assembly that allows for the adjustment of the inlet face with at least three degrees of freedom relative to the beam focuser; (xiii) wherein the optical assembly includes a plurality of spaced apart prisms; (xiv) wherein the optical assembly compresses the subassembly beams along an axis; (xv) wherein the first laser includes a first collimator that collimates the first laser beam, and a first beam corrector that further collimates the first laser beam; and/or (xvi) a mounting frame including a first frame that retains the lasers to form a first assembly level, and a second frame that retains the optical assembly to form a second assembly level; and a transfer assembly that transfers the subassembly beams from the first assembly level to the second assembly level.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is simplified top plan illustration of one implementation of a laser assembly;

FIG. 2A is simplified perspective illustration of another implementation of a laser assembly;

FIG. 2B is a cut-away view from FIG. 2A taken on line 2B-2B;

FIG. 2C is a cut-away view from FIG. 2A taken on line 2C-2C;

FIG. 3 is a simplified illustration of a portion of another implementation of a laser assembly;

FIG. 4 is a simplified illustration of another implementation of a portion of the laser assembly in partial cutaway secured to a structure;

FIG. 5A is a perspective view of another implementation of the laser assembly;

FIG. 5B is a perspective view of a portion of the laser assembly of FIG. 5A;

FIG. 5C is an alternative, perspective view of the portion of the laser assembly of FIG. 5B;

FIG. 5D is a perspective view of another portion of the laser assembly of FIG. 5A;

FIG. 5E is a perspective view of still another portion of the laser assembly of FIG. 5A;

FIG. 5F is a perspective view of yet another portion of the laser assembly of FIG. 5A;

FIG. 5G is a cut-away view taken on line 5G-5G in FIG. 5A;

FIG. 5H is an enlarged cut-away view of a portion of the laser assembly;

FIG. 5I is a perspective view of still another portion of the laser assembly of FIG. 5A;

FIG. 6 is a simplified top plan illustration of yet another implementation of a laser assembly; and

FIG. 7 is a top plan illustration of still another implementation of a laser assembly.

### DESCRIPTION

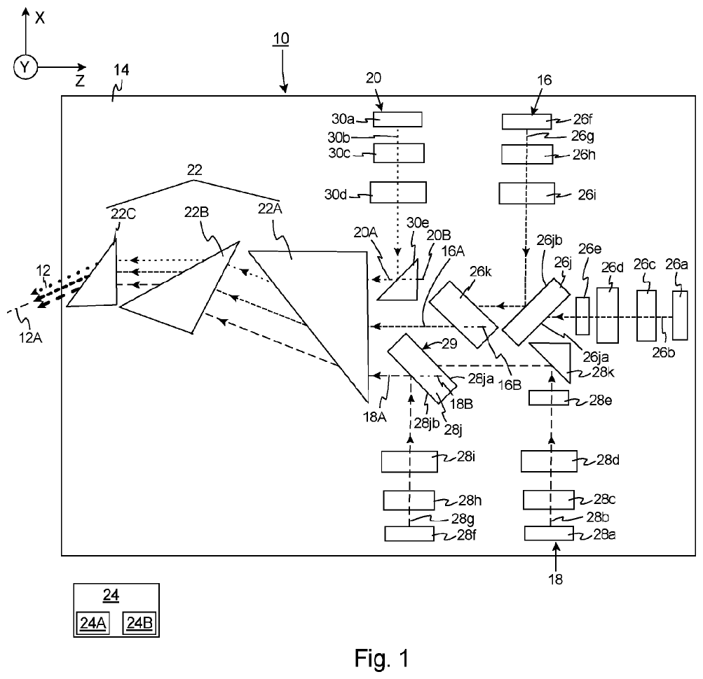

FIG. 1 is simplified top simplified, plan illustration of a laser assembly 10 that generates an output beam 12 (illustrated with three thick, solid arrows) along an output axis 12A. In this non-exclusive implementation, the laser assembly 10 includes (i) a mounting frame 14, (ii) a first laser subassembly 16 that generates a collimated, first subassembly beam 16A (illustrated with short dashed arrow); (iii) a second laser subassembly 18 that generates a collimated second subassembly beam 18A (illustrated with long dashed arrow); (iv) a third laser subassembly 20 that generates a collimated third subassembly beam 20A (illustrated with a dotted arrow); (v) an optical assembly 22 that receives and compresses/contracts the subassembly beams 16A, 18A, 20A to provide the output beam 12; and (vi) a system controller 24 that controls one or more of the components of the laser assembly 10. The design, size, position and/or shape of these components can be varied pursuant to the teachings provided herein. Further, the laser assembly 10 can be designed with more or fewer components than illustrated in FIG. 1, and/or the arrangement of these components can be different than that illustrated in FIG. 1.

A number of Figures include an orientation system that illustrates an X axis, a Y axis that is orthogonal to the X axis, and a Z axis that is orthogonal to the X and Y axes. It should be noted that these axes can also be referred to as the first, second, and third axes.

As an overview, the components of the laser assembly 10 are uniquely designed to have a relatively high power, the laser assembly 10 is optically and mechanically stable during temperature cycles and mechanical vibrations, and the laser assembly 10 has a relatively small form factor.

As non-exclusive examples, the laser assembly 10 can be designed so that the power output of the output beam 12 is at least one, two, three, four, five, or six Watts in the ultra-violet range, or at least one, two, three, four, five, six, seven, eight, or ten watts in the violet range. The high powered, laser assembly 10 disclosed herein can be used in a number of different applications. As non-exclusive examples, the laser assembly 10 can be used for medical applications, biomedical applications, scientific applications, or manufacturing.

The mounting frame 14 provides a rigid platform for supporting the laser subassemblies 16, 18, 20, and the optical assembly 22; and maintains these components in precise mechanical alignment. Additionally, the mounting frame 14 can include a temperature controller (not shown in FIG. 1) for controlling the temperature of the mounting base 14. Moreover, the mounting frame 14 can be designed to provide a controlled environment for some or all of the components. Non-exclusive examples of suitable materials for the mounting frame 14 include magnesium, aluminum, carbon fiber composite, moly copper, or copper tungsten.

In one implementation, the first laser subassembly 16 includes (i) a first laser 26a that generates a first laser beam 26b; (ii) a first collimator 26c that collimates the first laser beam 26b; (iii) a first beam corrector 26d; (iv) a first polarization rotator 26e; (v) a second laser 26f that generates a second laser beam 26g; (vii) a second collimator 26h that collimates the second laser beam 26g; (viii) a second beam corrector 26i; (ix) a first beam combiner 26j; and (x) a beam shifter 26k (e.g. a beam displacer) that cooperate to provide the first subassembly beam 16A along a first subassembly beam axis 16B to the optical assembly 22. It should be noted that the first laser subassembly 16 can be designed with more or fewer components than are illustrated in FIG. 1. For example, the first laser subassembly 16 could be designed without the beam shifter 26k.

The first laser 26a can include an emitter that directly generates the first laser beam 26b. For example, the emitter can be a laser diode. In one non-exclusive implementation, the first laser 26A is an ultra-violet emitter and the first laser beam 26b is in the ultra-violet wavelength range. The first laser 26a can be designed to generate the first laser beam 26b without tuning. Alternatively, the first laser 26a can be selectively tunable, or tuned/fixed to the desired wavenumber of the first laser beam 26b. For example, the first laser 26a can be designed so that the power output of the first laser beam 26b is at least 0.001, 0.01, 0.1, 1, 2, 3, 4, or 5 watts in the ultra-violet or violet range.

In one implementation, the first laser 26a emits the first laser beam 26b having a first polarization state. For example, the first laser 26a can be designed so that the first laser beam 26b is linearly polarized with the electric field polarization oriented along the Y axis of FIG. 1.

The first collimator 26c can include one or more elements (e.g. lenses) that approximately collimate the first laser beam 26b so that there will be minimal spread of the first laser beam 26b. For example, the first collimator 26c can include a lens made of fused silica, N-BK7HT, or any other material that is operable in the wavelength range of the first laser beam 26b. In one non-exclusive example, the first collimator 26c is a planar-aspherical with a focal length of 3.389 millimeters (f=3.389 millimeters) and a numerical aperture of 0.62 (NA=0.62). As alternative, non-exclusive embodiments, the first collimator 26c lens can have a diameter of less than approximately one, two, three, four, five or ten millimeters. In a non-exclusive embodiment, a Numerical Aperture of the first collimator 26c is chosen to approximately match a Numerical Aperture of the first laser 26a.

In certain implementations, the first collimator 26c does not fully collimate the first laser beam 26b. As alternative, non-exclusive implementations, the first collimator 26c is designed to collimate at least 75, 80, 85, 90, 95, 96, 97, 98, or 99 percent of the optical power of the first laser beam 26b.

The first beam corrector 26d is used to further collimate and fine tune the collimation of the first laser beam 26b that exits the first collimator 26c. The first beam corrector 26d is used to compensate for any movement that occurs during temperature cycling during manufacturing. With this design, the first laser 26a can be operated and thermally cycled for a period of time during manufacturing. Subsequently, the first beam corrector 26d can be added and finely adjusted to correct the collimation and pointing of the first laser beam 26b after the first laser 26a has been temperature and/or vibration cycled. As a result thereof, the laser assembly 10 will be less sensitive to further temperature cycling and vibration. Moreover, this will enhance the subsequent beam combining and will maximize the power of the output beam 12 when the multiple beams are combined. With this design, the first beam corrector 26d can be used to compensate for alignment errors that occur in the optics during initial temperature cycles and vibration, and the first beam corrector 26d offers diffraction limited performance.

For example, the first beam corrector 26d can be made of N-BK7HT, S-BSL7, or and other material that is operable in the wavelength range of the first laser beam 26b. In one non-exclusive implementation, the first beam corrector 26d is a bore-sight corrector that can be selectively adjusted and set after the laser assembly 10 has been operated for a sufficient time (with sufficient temperature and/or vibration cycling) and optics have settled. With this design, the first beam corrector 26d can be controlled to fine tune the characteristics (e.g., the collimation) of the first laser beam 26b to correct for movement of the first collimator 26c after the initial temperature and/or vibration cycling. As alternative, non-exclusive implementations, the first beam corrector 26d is designed to collimate less than 25, 20, 15, 10, 5, 4, 3, 2, or 1 percent of the optical power of the first laser beam 26b. In one non-exclusive example, the first beam corrector 26d is spherical-planar with a focal length of 78.6 millimeters (f=78.6 millimeters) and a numerical aperture of 0.042 (NA=0.042). In a specific, non-exclusive example, the first collimator 26c collimates ninety percent of the optical power and the first beam corrector 26d collimates ten percent of the optical power. As a result thereof, the first collimator 26c and the first beam corrector 26d cooperate to be equivalent to a single collimating lens.

The first polarization rotator 26e changes the polarization of the first laser beam 26b. In one embodiment, the polarization rotator 26e is a transmissive one-half wave waveplate that changes the polarization of the first laser beam 26b from the first polarization state to a second polarization state. With this design, the polarization of the first laser beam 26e having the electric field polarization oriented along the Y axis is rotated to the electric field polarization being oriented along X axis as the first laser beam 26b is transmitted through the first polarization rotator 26e.

In one example, the first polarization rotator 26e is a zero-order waveplate that includes two quartz plates. These plates can be separated by a spacer or not separated. Alternatively, the first polarization rotator 26e can be rhomboid prism or other polarization rotator.

The second laser 26f can be similar to the first laser 26a described above. In one non-exclusive implementation, the second laser 26f is an ultra-violet emitter and the second laser beam 26g is in the ultra-violet wavelength range. Further, the second laser 26f can emit the second laser beam 26g having the first polarization state. In one non-exclusive implementation, the wavenumber of the second laser beam 26g is approximately equal to the wavenumber of the first laser beam 26b.

The second collimator 26h can be similar in design to the first collimator 26c described above.

The second beam corrector 26i is used to further collimate and fine tune the collimation of the second laser beam 26g that exits the second collimator 26h. The second beam corrector 26i can be similar in design to the first beam corrector 26d described above. With this design, the second beam corrector 26g can be adjusted to fine tune the characteristics (e.g., the collimation) of the second laser beam 26g after the second laser 26f has been operated and thermally cycled for a period of time during manufacturing. Stated in another fashion, the second beam corrector 26i can correct for movement of the second collimator 26h during temperature cycling during manufacturing.

The first beam combiner 26j combines the first laser beam 26b and the second laser beam 26g to provide the first subassembly beam 16A. In one, non-exclusive implementation, the first beam combiner 26j is a polarization beam combiner that reflects light at the first polarization state and transmits light at the second polarization state. For example, the first beam combiner 26j can reflect light having the electric field polarization oriented along the Y axis, and transmit light having the electric field polarization oriented along the X axis. Stated in another fashion, the first beam combiner 26j can reflect light having the electric field S-polarization, and transmit light having the electric field P-polarization.

In FIG. 1, the first beam combiner 26j is at an approximately forty-five (45) degree angle relative to the Z axis, and includes (i) a first combiner side 26ja that generally faces the first laser 26a; and (ii) an opposed second combiner side 26jb that generally faces the optical assembly 22 and the second laser 26f. In this design, the first combiner side 26ja includes an anti-reflective coating, and the second combiner sider 26jb includes a polarization beam combining coating that reflects light at the first polarization state and transmits light at a second polarization state.

With this design, the first laser beam 26b is refracted by the first combiner side 26ja and transmitted through the second combiner side 26jb to the beam shifter 26k; and the second laser beam 26g is reflected ninety degrees with the second combiner side 26jb at the beam shifter 26k. Stated in another fashion, the second laser beam 26g is reflected by the second combiner side 26jb (because it is at the first polarization state) and the first laser beam 26b is transmitted through the second combiner side 26jb (because it is at the second polarization state). With this design, the second laser beam 26g combines with the first laser beam 26b at the second combiner side 26jb to generate the first subassembly beam 16A.

The beam shifter 26k shifts the first subassembly beam 16A so that the first subassembly beam 16A is directed along a first subassembly axis 16B at the optical assembly 22. In the non-exclusive implementation of FIG. 1, the first subassembly axis 16B is parallel to the Z axis. For example, the beam shifter 26k can be a refractive element, such as a window or periscope. It should be noted that the beam shifter 26k is optional and is used allow for the desired positioning of the components of the laser assembly 10.

In one implementation, the second laser subassembly 18 is similar to the first laser subassembly 16 described above. For example, the second laser subassembly 18 can include (i) a third laser 28a that generates a third laser beam 28b; (ii) a third collimator 28c that collimates the third laser beam 28b; (iii) a third beam corrector 28d; (iv) a second polarization rotator 28e; (v) a fourth laser 28f that generates a fourth laser beam 28g; (vii) a fourth collimator 28h that collimates the fourth laser beam 28g; (viii) a fourth beam corrector 28i; (ix) a second beam combiner 28j; and (x) a first beam redirector 28k that cooperate to provide the second subassembly beam 18A along a second subassembly beam axis 18B to the optical assembly 22. In the non-exclusive implementation of FIG. 1, the second subassembly axis 18B is substantially parallel with the first subassembly axis 16B and the Z axis. It should be noted that the second laser subassembly 18 can be designed with more or fewer components than are illustrated in FIG. 1. For example, the second laser subassembly 18 could be designed without the first beam redirector 28k.

The third laser 28a and the fourth lasers 28f can be similar to the first laser 26a described above. In one non-exclusive implementation, the third and fourth lasers 28a, 28f can each be an ultra-violet emitter and the laser beams 28b, 28g can be in the ultra-violet wavelength range. Further, the emitted the laser beams 28b, 28g can have the first polarization state. In one non-exclusive implementation, the wavenumber of each laser beam 28b, 28g is approximately equal to the wavenumber of the first laser beam 26b.

The third and fourth collimators 28c, 28h can be similar in design to the first collimator 26c described above.

The third and fourth beam corrector 28d, 28i can be similar in design to the first beam corrector 26d described above. With this design, the third and fourth beam correctors 28d, 28i can be individually adjusted to fine tune the characteristics (e.g. the collimation) of the laser beam 28b, 28g after the laser 28a, 28f has been operated and thermally cycled for a period of time during manufacturing.

The second polarization rotator 28e can be similar to the first polarization rotator 26e described above.

The second beam combiner 28j combines the third laser beam 28b and the fourth laser beam 28g to provide the second subassembly beam 18A. In one, non-exclusive implementation, the second beam combiner 28j is similar to the first beam combiner 26j described above.

It should be noted that the first beam combiner 26j and the second beam combiner 28j can be collectively or individually referred to as a beam combiner assembly 29. Further, it should be noted that in FIG. 1, the first beam combiner 26j and the second beam combiner 28j are illustrated as separate components that are spaced apart. However, in other embodiments, the first beam combiner 26j and the second beam combiner 28j can be combined to form a single beam combiner assembly 29.

The first beam redirector 28k redirects the third laser beam 28b to the second beam combiner 28j. For example, the first beam redirector 28k can be turn mirror.

In one implementation, the third laser subassembly 20 can be somewhat similar to the first laser subassembly 16 described above. However, in FIG. 1, the third laser subassembly 20 includes a single laser, instead of two lasers. More specifically, the third laser subassembly 20 can include (i) a fifth laser 30a that generates a fifth laser beam 30b; (ii) a fifth collimator 30c that collimates the fifth laser beam 30b; (iii) a fifth beam corrector 30d; and (iv) a second beam redirector 30e that cooperate to provide the third subassembly beam 20A along a third subassembly beam axis 20B to the optical assembly 22. In the non-exclusive implementation of FIG. 1, the third subassembly axis 20B is substantially parallel to the second subassembly axis 18B, the first subassembly axis 16B, and the Z axis. It should be noted that the third laser subassembly 20 can be designed with more or fewer components than are illustrated in FIG. 1.

The fifth laser 30a can be similar to the first laser 26a described above. In one non-exclusive implementation, the fifth laser 30a can each be an ultra-violet emitter and the fifth laser beam 30b can be in the ultra-violet wavelength range. Further, the emitted the fifth laser beam 30b can have the first polarization state. In one non-exclusive implementation, the wavenumber of the fifth laser beam 30b is approximately equal to the wavenumber of the first laser beam 26b.

The fifth collimator 30c can be similar in design to the first collimator 26c described above.

The fifth beam corrector 30d can be similar in design to the first beam corrector 26d described above. With this design, the fifth beam corrector 30d can be adjusted to fine tune the characteristics (e.g., the collimation) of the fifth laser beam 30b after the fifth laser 30a has been operated and thermally cycled for a period of time during manufacturing.

The second beam redirector 30e redirects the fifth laser beam 30b along the third subassembly beam axis 20b. For example, the second beam redirector 30e can be turn mirror.

In the non-exclusive implementation of FIG. 1, the subassembly beams 16A, 18A, 20A are parallel to each other and spaced apart along the X axis in a X-Z plane. Further, each of the subassembly beams 16A, 18A, 20A is a cone of energy that is illustrated as a dashed line, that represents the center of the respective subassembly beams 16A, 18A, 20A. In alternative, non-exclusive implementations, before the subassembly beams 16A, 18A, 20A enter the optical assembly 22, the center of adjacent subassembly beams 16A, 18A, 20A are spaced apart at least 0.1, 1, 3, or 10 millimeters. In certain implementations, the beams 16A, 18A, 20A are as close as possible to conserve brightness.

It should be noted that although the centers of the subassembly beams 16A, 18A, 20A are illustrated as being spaced apart significantly before entry in the optical assembly 22, because each the subassembly beams 16A, 18A, 20A is a cone of energy, the subassembly beams 16A, 18A, 20A are actually adjacent to each other.

The optical assembly 22 compresses/contracts the subassembly beams 16A, 18A, 20A so that the spacing between the subassembly beams 16A, 18A, 20A beams is reduced and the diameter of each subassembly beams 16A, 18A, 20A is reduced. The design of the optical assembly 22 can be varied pursuant to the teachings provided herein. As alternative, non-exclusive examples, the optical assembly 22 can compress the spacing between the centers of the subassembly beams 16A, 18A, 20A at least approximately 1.5, 2, 4, 10, 20, 50, or 100 times. Further, the optical assembly 22 can compress the diameter of each of the subassembly beams 16A, 18A, 20A at least approximately 1.5, 2, 4, 10, 20, 50, or 100 times.

With this design, the output beam 12 is made of the three subassembly beams 16A, 18A, 20A compressed together. In alternative, non-exclusive implementations, after the subassembly beams 16A, 18A, 20A exit the optical assembly 22, centers of adjacent subassembly beams 16A, 18A, 20A are spaced apart at less than 0.1, 0.5, 1, or 2 millimeters.

Moreover, in alternative, non-exclusive implementations, after the subassembly beams 16A, 18A, 20A exit the optical assembly 22, the outer beam 12 has a cross-sectional area of less than 0.02 mm\hat{ }2, 1 mm\hat{ }2, 3.5 mm\hat{ }2, 7.0 mm\hat{ }2 or 35 mm\hat{ }2 (millimeters squared).

It should be noted that in certain implementations, (i) the first subassembly beam 16A has both S-polarization and P-polarization; (ii) the second subassembly beam 18A has both S-polarization and P-polarization; and (iii) the third subassembly beam 20A has only S-polarization.

In the non-exclusive implementation of FIG. 1, the optical assembly 22 is a prism compressor that includes a plurality of spaced apart prisms, such as a first prism 22A, a second prism 22B, and a third prism 22C that are spaced apart. As an example, each prism 22A, 22B, 22C can be a YAG prism. In FIG. 1, each prism 22A, 22B, 22C is a right triangular shaped prism. With this design, the optical assembly 22 compresses the spacing and the diameter of the subassembly beams 16A, 18A, 20A to provide the output beam 12.

The prisms 22A, 22B, 22C are arranged and designed to be athermal and achromatic, and only compress the beams 16A, 18A, 20A along one axis. In angular space, the beams diverge more in the axis they are compressed.

Alternatively, for example, the optical assembly 22 could use two cylindrical lens, somewhat similar to a telescope, or could have a different configuration.

The system controller 24 controls one or more of the components of the laser assembly 10. For example, the system controller 24 can direct current to each laser subassembly 16, 18, 20. The system controller 24 can include one or more processors 24A, one or more electronic storage devices 24B, one or more circuit boards, and/or one or more connectors. The system controller 24 is illustrated in FIG. 1 as a centralized system. Alternatively, the system controller 24 can be a distributed system.

The laser assembly 10 can be powered by a generator, a battery, or another power source that provides power to the system controller 24.

As provided herein, the beam correctors 26d, 26i, 28d, 28i, 30d allow for the laser beams 26a, 26g, 28a, 28g, 30a to be tuned after the optics have settled (e.g., after sufficient temperature cycles and mechanical vibrations) to accurately collimate and accurately point. This will result in a higher powered and more accurate output beam 12. It should be noted that the design and arrangement of the components of the laser assembly 10 allow for the laser assembly 10 to have a relatively high output power because the output of multiple lasers 26a, 26f, 28a, 28f, 30a are accurately combined, while being optically and mechanically stable because the beam correctors 26d, 26i, 28d, 28i, 30d are used after the optics have settled (e.g., from temperature cycles and mechanical vibrations). As a result thereof, the laser assembly 10 is relatively insensitive to subsequent temperature cycles and mechanical vibrations of the laser assembly 10. In certain implementations, this allows for output of multiple lasers (e.g., 2, 3, 4, 5 or 6 lasers) to be accurately combined and fiber coupled into a single optical fiber.

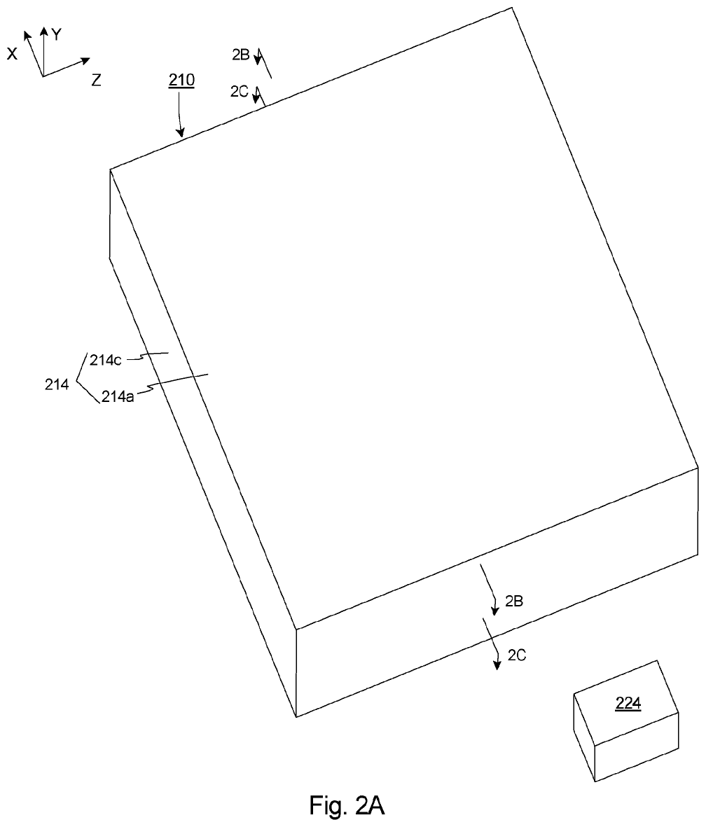

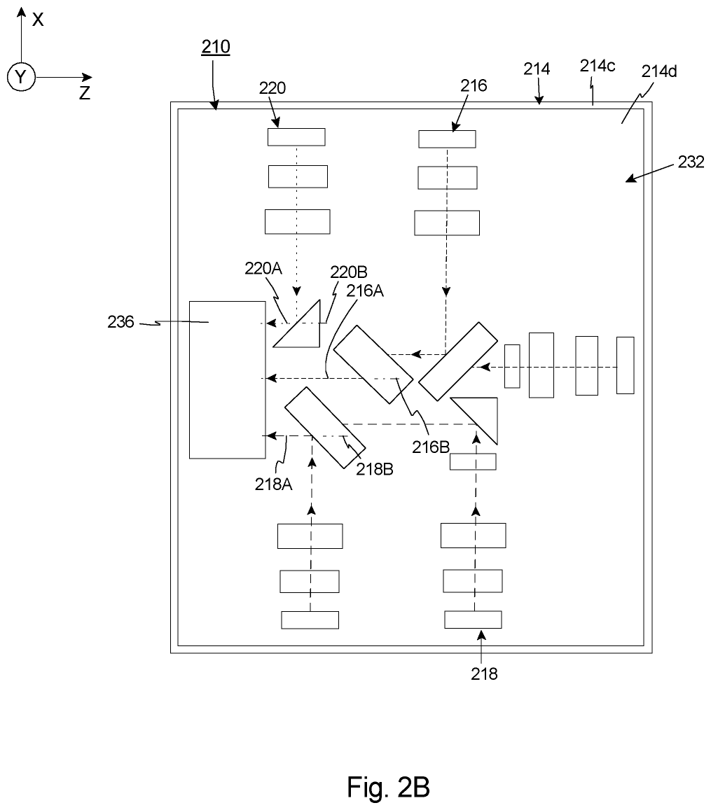

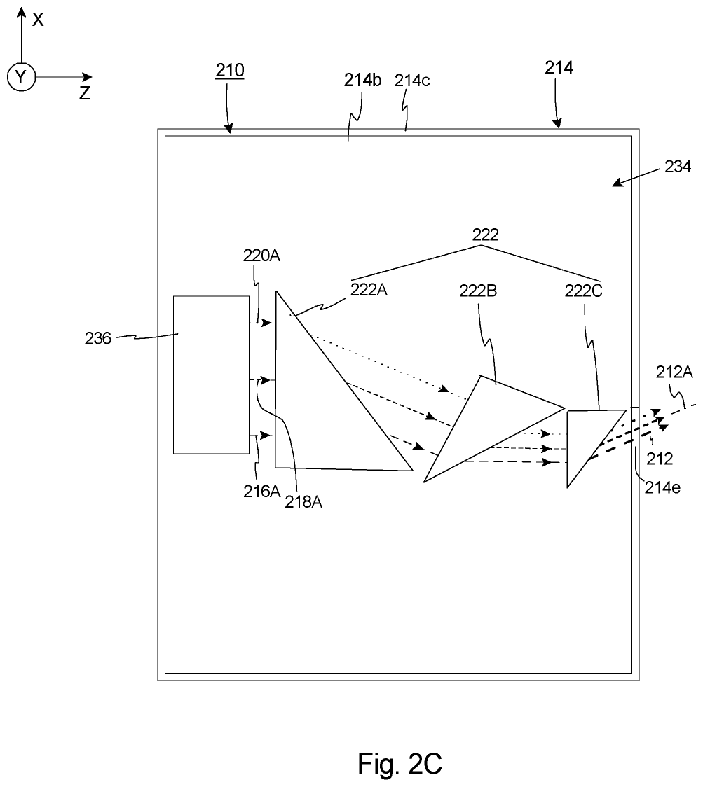

FIG. 2A is simplified top, perspective illustration of another implementation of a laser assembly 210. In FIG. 2A, the mounting frame 214 and the system controller 224 are visible. These components are somewhat similar to the corresponding components described above. However, in this implementation, the components of the laser assembly 210 are arranged in a multiple level setup. As a result thereof, the laser assembly 210 can have a smaller form factor than the design illustrated in FIG. 1. In FIG. 2A, the mounting frame 214 is rigid and forms a controlled environment for most of the components of the laser assembly 210. In this implementation, the mounting frame 214 includes (i) a generally rectangular plate shaped top frame 214a, (ii) a generally rectangular plate shaped bottom frame 214b (illustrated in FIG. 2C); (iii) a generally rectangular tube-shaped side wall assembly 214c that includes four walls; and (iv) a generally rectangular plate shaped intermediate frame 214d (illustrated in FIG. 2B) positioned between the top frame 214a, and the bottom frame 214b. In this design, the side wall assembly 214c separates the top frame 214a from the bottom frame 214b. It should be noted that any of the top frame 214a, the bottom frame 214b, and the intermediate frame 214d can alternatively be referred to as a first frame, a second frame or a third frame.

FIG. 2B is cut-away view of the laser assembly 210 taken on line 2B-2B in FIG. 2A, and FIG. 2C is cut-away view of the laser assembly 210 taken on line 2C-2C in FIG. 2A. FIG. 2B illustrates that the laser assembly 210 includes an upper, first assembly level 232; while FIG. 2C illustrates that the laser assembly 210 includes a lower, second assembly level 234. With reference to FIGS. 2B and 2C, the first assembly level 232 is positioned above the second assembly level 234. Alternatively, for example, the first assembly level 232 can be positioned below the second assembly level 234. Alternatively, the two levels 232, 234 can be side-by-side. Still alternatively, the laser assembly 210 can be designed to include more than two or fewer than two assembly levels.

As non-exclusive examples, the laser assembly 210 can have a form factor of less than 53 by 48 by 22 millimeters. Stated in another fashion, in alternative, non-exclusive implementations, the laser assembly 210 has a volume of less than 40, 50, 56, 60, or 70 centimeters cubed.

With reference to FIG. 2B, the top frame 214a (illustrated in FIG. 2A) has been removed, and the first assembly level 232 is now visible. In this implementation, the mounting frame 214 includes the rigid, intermediate frame 214d that extends between the side wall assembly 214c, intermediate the top frame 214a and the bottom frame 214b (illustrated in FIG. 2C). In this design, the intermediate frame 214d is generally rectangular plate shaped and is positioned substantially parallel to the top frame 214a and the bottom frame 214b.

Further, in this design, the laser assembly 210 includes a first laser subassembly 216, a second laser subassembly 218, and a third subassembly 220 that are secured/coupled to the intermediate frame 214d to form part of the first assembly level 232. In this implementation, the first laser subassembly 216, the second laser subassembly 218, and the third laser subassembly 220 can be similar to the corresponding components described above in reference to FIG. 1. Similarly, in this implementation, (i) the first laser subassembly 216 generates a collimated, first subassembly beam 216A (illustrated with short dashed arrow) along the first subassembly beam axis 216B; (ii) the second laser subassembly 218 generates a collimated second subassembly beam 218A (illustrated with long dashed arrow) along the second subassembly beam axis 218B; and (iii) the third laser subassembly 220 generates a collimated third subassembly beam 220A (illustrated with a dotted arrow) along the third subassembly beam axis 220B.

Additionally, in this implementation, the laser assembly 210 includes a transfer assembly 236 (illustrated as a box) that transfers the subassembly beams 216A, 218A, 220A from the first assembly level 232 to the second assembly level 234. In this design, the transfer assembly 236 is part of both levels 232, 234.

As a non-exclusive example, the transfer assembly 236 can be a dove prism that directs the subassembly beams 216A, 218A, 220A from the first assembly level 232 to the second assembly level 234 (changes the position of the subassembly beams 216A, 218A, 220A along the Y axis) without significantly altering the spacing of the subassembly beams 216A, 218A, 220A along the X axis. As illustrated in FIG. 2B, the subassembly beams 216A, 218A, 220A are moving from right to left along the Z axis, and are spaced apart along the X axis prior to entering the transfer assembly 236.

With reference to FIG. 2C, the intermediate frame 214c (illustrated in FIG. 2B) has been removed, and the second assembly level 234 with the bottom frame 214b and the side wall assembly 214c is now visible. In this design, the transfer assembly 236 has transferred the subassembly beams 216A, 218A, 220A from the first assembly level 232 (in FIG. 2B) to the second assembly level 234 without significantly altering the spacing of the subassembly beams 216A, 218A, 220A. As illustrated in FIG. 2C, the subassembly beams 216A, 218A, 220A are moving from left to right along the Z axis, and are spaced apart along the X axis upon exiting the transfer assembly 236. Comparing FIGS. 2B and 2C, the transfer assembly 236 has shifted the subassembly beams 216A, 218A, 220A along the Y axis, and has reversed the direction of travel of the subassembly beams 216A, 218A, 220A along the Z axis.

Further, in FIG. 2C, the optical assembly 222 includes a first prism 222A, a second prism 222B, and a third prism 222C which are similar to the corresponding components described above and illustrated in FIG. 1. With this design, optical assembly 222 receives and compresses in one axis the subassembly beams 216A, 218A, 220A to provide the output beam 212 along the output axis 212A.

Additionally, the mounting frame 214 can include a window 214e that allows the output beam 212 to exit the mounting frame 214. For example, the window 214e can be an opening or made of a material that is transparent to the output beam 212.

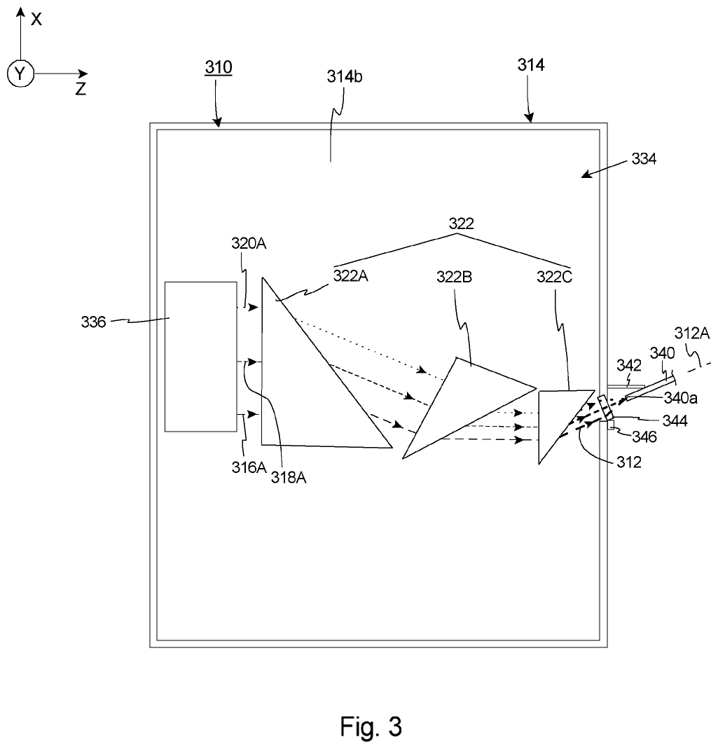

FIG. 3 is a simplified cut-away view of a portion of yet another implementation of a laser assembly 310 that is somewhat similar to the laser assembly 210 described above and illustrated in FIGS. 2A-2C. However, in FIG. 3, the laser assembly 310 is a fiber coupled laser assembly. In FIG. 3, only the second assembly level 334 is shown. However, the laser assembly 310 of FIG. 3 can include a first assembly level with multiple laser subassemblies similar to the embodiment described above illustrated in FIG. 2B.

In FIG. 3, the second assembly level 334 includes the bottom frame 314b of the mounting frame 314, a portion of the transfer assembly 336, and the optical assembly 322 including the prisms 322A, 322B, 322C that are similar to the corresponding components described above. In this design, the transfer assembly 336 has transferred the subassembly beams 316A, 318A, 320A from the first assembly level (not shown in FIG. 3) to the second assembly level 334 without significantly altering the spacing of the subassembly beams 316A, 318A, 320A. Further, the optical assembly 322 receives and contracts the subassembly beams 316A, 318A, 320A to provide the output beam 312 along the output axis 312A.

Additionally, in this implementation, the laser assembly 310 includes (i) a fiber assembly 340; (ii) a fiber attachment assembly 342 (illustrated as a box); (iii) a beam focuser 344; and (iv) a focuser attachment assembly 346 (illustrated as a box). The design of each of these components can be varied pursuant to the teachings provided herein.

The fiber assembly 340 includes at least on optical fiber having an inlet facet 340a. For example, the inlet facet 340a can include an anti-reflective coating for the wavelengths of the output beam 312.

The fiber attachment assembly 342 attaches the fiber assembly 342 to the mounting frame 314 or other component of the laser assembly 310. In certain implementations, the fiber attachment assembly 342 allows for the position of the inlet facet 340a to be moved with multiple (e.g. three, four, five, or six) degrees of freedom relative to the beam focuser 344, and subsequently fixed relative to the beam focuser 344. With this design, the position of the inlet facet 340a can be adjusted (and subsequently set) so that the maximum amount of output beam 312 power is directed at the inlet facet 340a and accepted by the optical fiber.

The beam focuser 344 focuses the output beam 312 from the optical assembly 322 onto the inlet facet 340a. For example, the beam focuser 344 can include one or more convex lenses that use refraction to focus the output beam 312 onto the inlet facet 340a.

The focuser attachment assembly 346 attaches the beam focuser 344 to the mounting frame 314 or other component of the laser assembly 310. In certain implementations, the focuser attachment assembly 346 allows for the position of the beam focuser 344 to be moved with multiple (e.g. three, four, five, or six) degrees of freedom relative to the output beam 312 and the optical assembly 322, and subsequently fixed relative to the output beam 312, the optical assembly 322, and the mounting frame 314. With this design, the position of the beam focuser 344 can be adjusted (and subsequently set) so that the output beam 312 is accurately focused at a precise location in a plane. Subsequently, the inlet facet 340a can be accurately positioned at that precise location in that plane.

A non-exclusive example of a suitable fiber attachment assembly 342 and a suitable focuser attachment assembly 346 are described in more detail below.

In a non-exclusive example, the output beam 312 can be fiber coupled to a fiber assembly 340 having a fiber core that is fifty microns in diameter and a fiber numerical aperture that is 0.22.

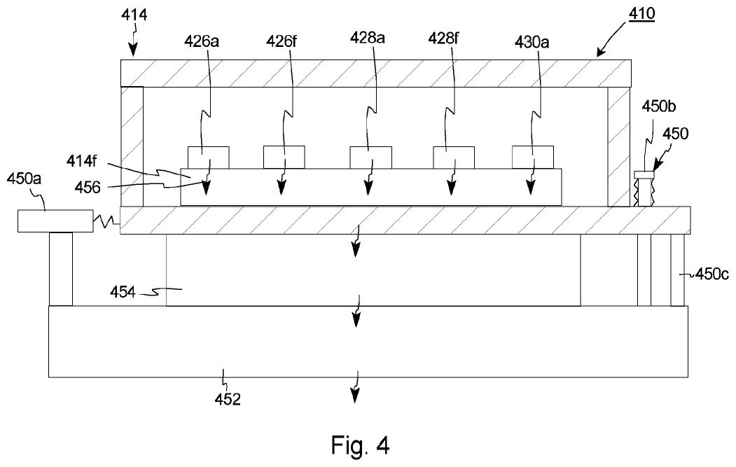

FIG. 4 is a simplified side illustration (in partial cutaway) of another implementation of the laser assembly 410 illustrating a possible, non-exclusive example of the mounting and temperature control for the laser assembly 410. In this non-exclusive implementation, an attachment assembly 450 attaches the laser assembly 410 to a rigid structure 452 (e.g. a heatsink) with a temperature control unit 454 (e.g. a thermoelectric cooler) therebetween. However, the laser assembly 410 can be retained in a fashion different than illustrated in FIG. 4.

It should be noted that many of the components of the laser assembly 410 are not illustrated in FIG. 4. More specifically, in FIG. 4, only the mounting frame 414, and the lasers 426a, 426f, 428a, 428f, 430a are illustrated. In this implementation, the mounting frame 414 forms an enclosed housing (chamber) around the other components of the laser assembly 410. Additionally, the mounting frame 414 can include a laser mount 414f that secures the lasers 426a, 426f, 428a, 428f, 430a. The laser mount 414f can be made of a material having a high heat transfer rate to readily remove heat from the lasers 426a, 426f, 428a, 428f, 430a.

With this design, heat 356 (represented with arrows) is primarily transferred from the lasers 426a, 426f, 428a, 428f, 430a to the laser mount 414f. Next, the heat 456 is transferred to the temperature control unit 454. Subsequently, the heat 456 is transferred from the temperature control unit 454 to the structure 452.

The design of the attachment assembly 450 for securing the laser assembly 410 to the structure 452 can be varied. For example, the attachment assembly 450 can include (i) one or more flexures 450a, (ii) one or more fasteners 450b (e.g. shoulder bolts with spring loading); and/or (iii) one or more alignment pins 450c. However, other attachment assemblies 450 can be utilized.

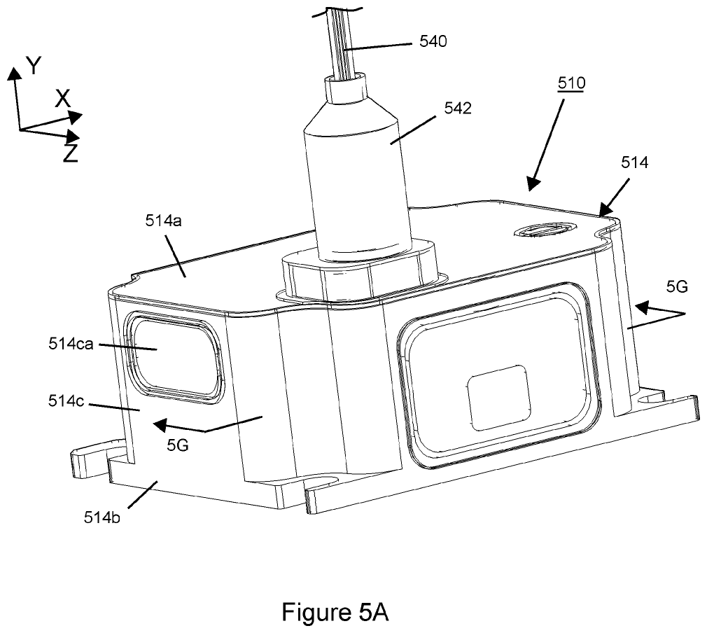

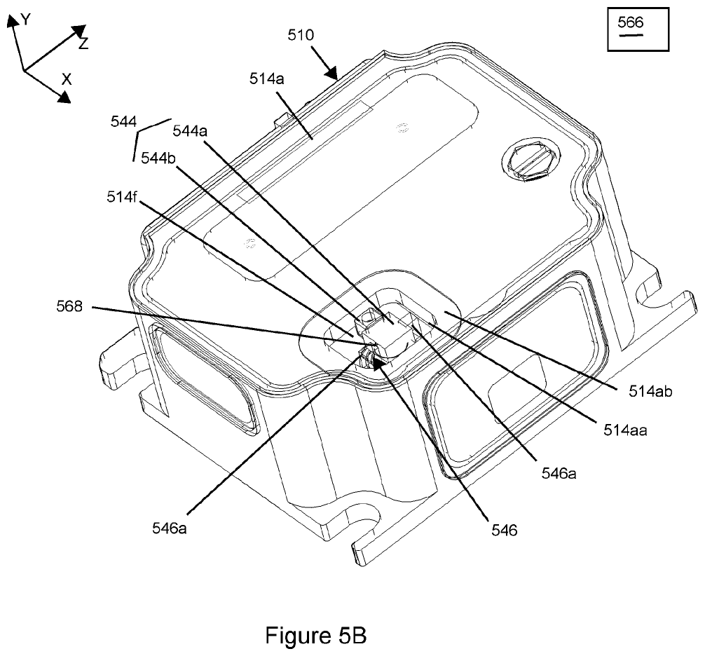

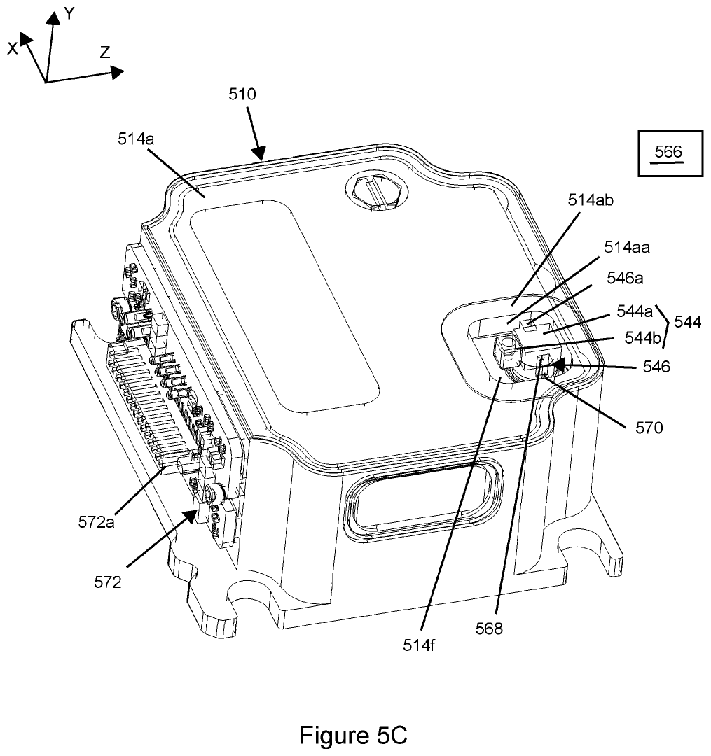

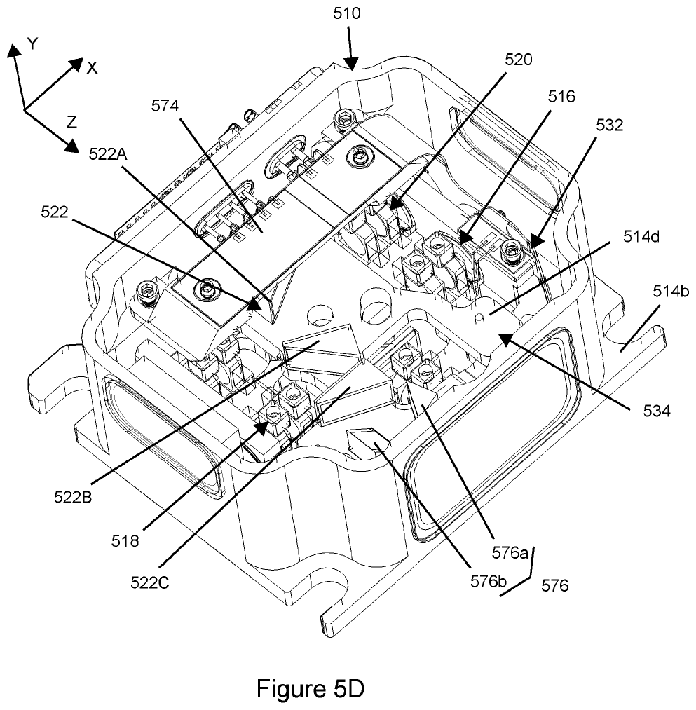

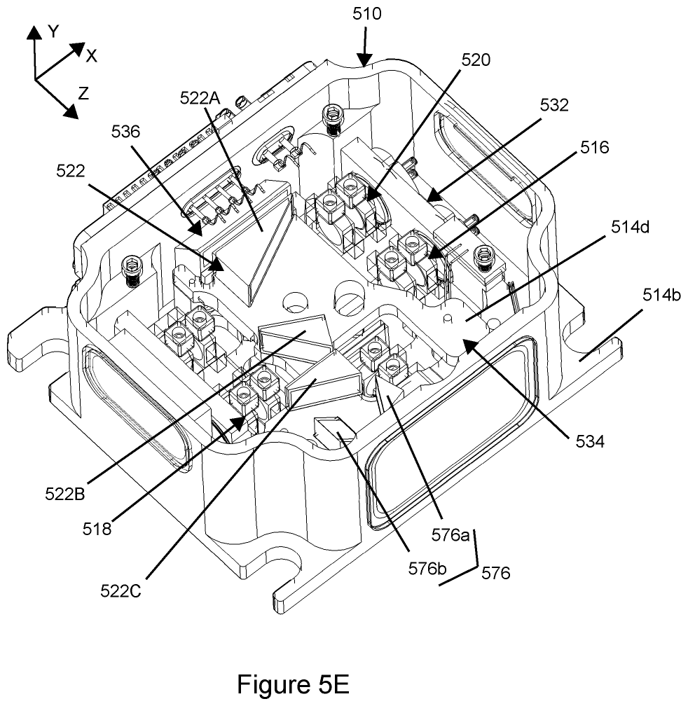

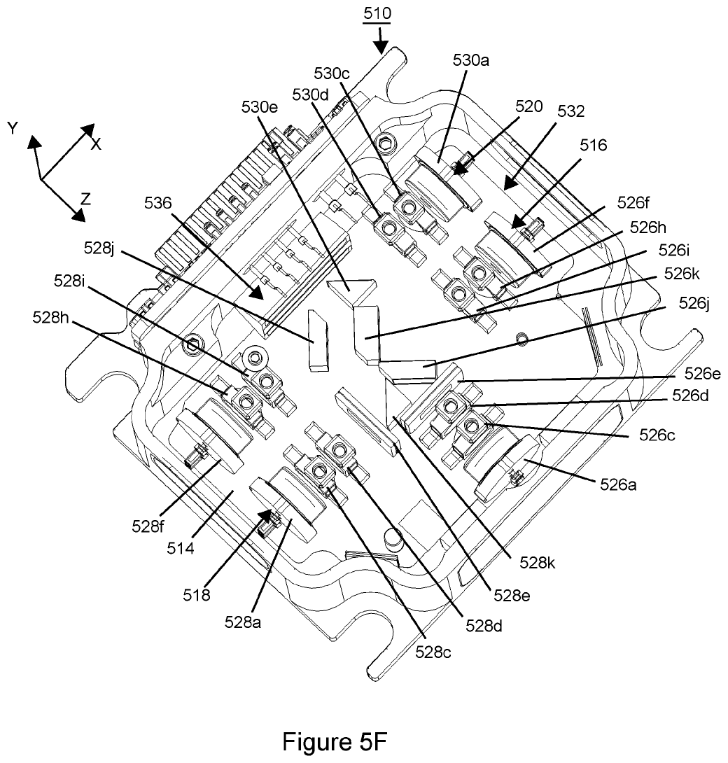

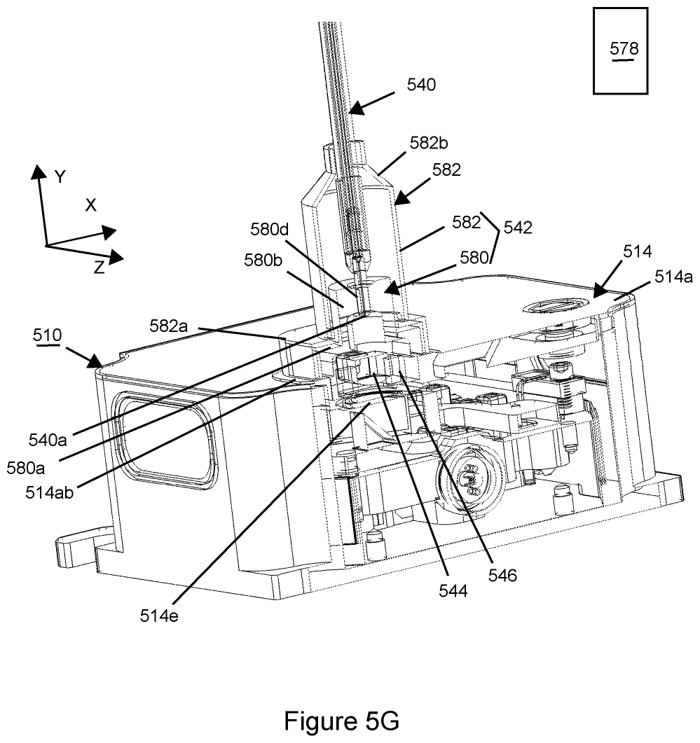

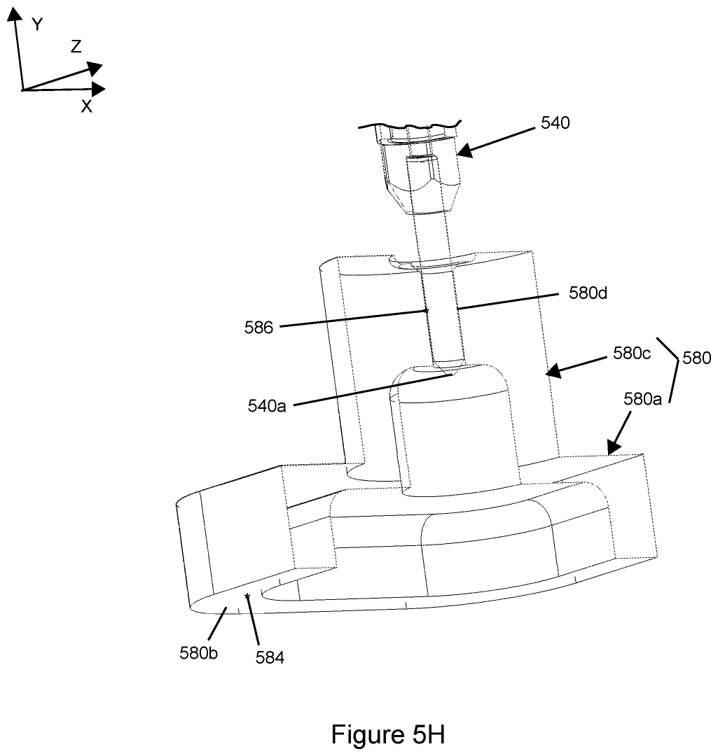

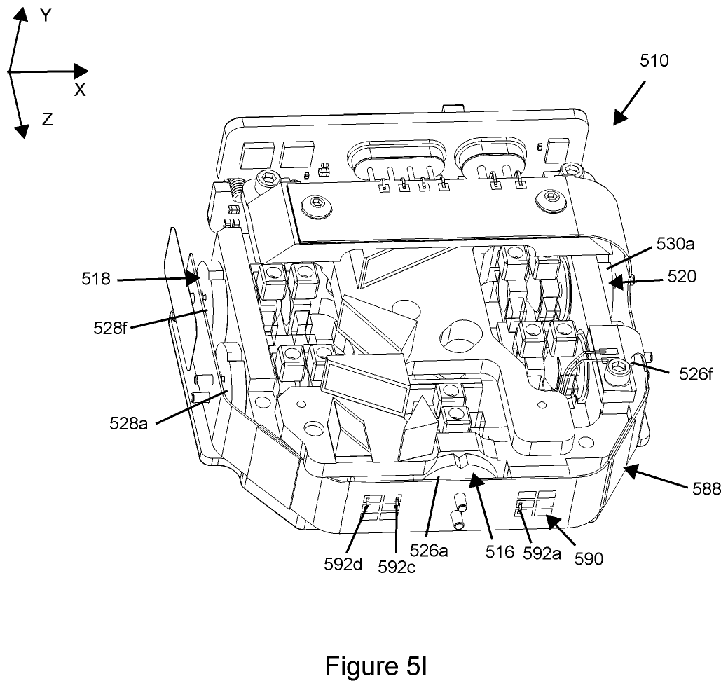

FIG. 5A is a perspective view of another implementation of the laser assembly 510. In FIG. 5A, (i) a mounting frame 514 with the top frame 514a, the bottom frame 514b, and the side wall assembly 514c; (ii) a fiber assembly 540; and (iii) a fiber attachment assembly 542 are shown. These components can be similar to the corresponding components described above. In this implementation, the laser assembly 510 is a fiber coupled. Stated in another fashion, the energy generated by the laser assembly 510 is directed into the fiber assembly 540. In this implementation, the fiber assembly 540 is secured to the top frame 514a.

Additionally, it should be noted that the mounting frame 514 (e.g., the side wall assembly 514c) can include one or more removable, sealable, access doors 514ca that allow for access to the inner components during assembly and alignment of the components within the mounting frame 514.

FIGS. 5B and 5C are alternative perspective views of a portion of the laser assembly 510 of FIG. 5A, with the fiber assembly 540 (illustrated in FIG. 5A) and the fiber attachment assembly 542 (illustrated in FIG. 5A) removed. As a result thereof, the beam focuser 544 and the focuser attachment assembly 546 are visible. These components can be similar to the corresponding components described above.

In one, non-exclusive implementation, (i) the top frame 514a includes a recessed region 514aa that having a focuser attachment surface 514f; (ii) the beam focuser 544 includes a convex lens 544a and a tooling block 544b that is fixedly secured to the convex lens 544a; and (ii) the focuser attachment assembly 546 includes a pair of attachment blocks 546a that are used to fixedly secure the beam focuser 544 to the attachment surface 514f. With this design, a focuser alignment tool 566 (illustrated as a box in FIGS. 5B and 5C) can grip and retain the beam focuser 544 via the tooling block 544b. The focuser alignment tool 566 can be designed and used to move and precisely position the beam focuser 544 with multiple (e.g. three, four, five, or six) degrees of freedom relative to the focuser attachment surface 514f. For example, the focuser alignment tool 566 can include one or more translation stages and goniometers that move and position the beam focuser 544 with six degrees of freedom relative to the optical assembly (illustrated in FIG. 5D) and the focuser attachment surface 514f.

In certain implementations, the focuser attachment assembly 546 allows for the position of the beam focuser 544 to be accurately moved with multiple (e.g. three, four, five, or six) degrees of freedom relative to the output beam (not shown in FIGS. 5B and 5C) and the optical assembly 522 by the focuser alignment tool 566, and subsequently fixed relative to the output beam, the optical assembly 322, and the mounting frame 514. With this design, the laser subassemblies 516, 518, 520 (illustrated in FIG. 5D) can be individually or jointly activated, and the position of the beam focuser 344 can be finely adjusted with the focuser alignment tool 566 (and subsequently set) so that the three subassembly beams (not shown in FIGS. 5C and 5D) of the output beam are accurately focused at a precise target location in a target plane. In a specific example, the focuser attachment assembly 546 allows for the position of the beam focuser 544 to be accurately moved with at least three degrees of freedom (e.g., along the X, Y, and Z axes) relative to the output beam and the optical assembly 522. In another specific example, the focuser attachment assembly 546 allows for the position of the beam focuser 544 to be accurately moved with at least five degrees of freedom (e.g., along the X, Y, and Z axes, and about the X and Z axes) relative to the output beam and the optical assembly 522.

After the beam focuser 544 is precisely positioned, (i) a first block adhesive 568 (illustrated with an asterisk symbol) can be used to fixedly secure the attachment blocks 546a to the convex lens 544a; and (ii) a second block adhesive 570 (illustrated with an asterisk symbol) can be used to fixedly secure the attachment blocks 546a to the focuser attachment surface 514f. For example, each adhesive 568, 570 can be an ultra-violet light curable glue and the attachment blocks 546a can be transparent to ultra-violet light. With this design, after the beam focuser 544 is precisely positioned, ultra-violet light can be directed at the adhesives 568, 570 to cure the adhesives 578, 570 and fixedly secure the convex lens 544a to the focuser attachment surface 514f. Subsequently, the focuser alignment tool 566 can be removed, and the laser assembly 510 can be moved to an oven (not shown) to fully cure the adhesive.

It should be noted that FIGS. 5B and 5C also illustrate that the mounting frame 514 (e.g., the top frame 514a) can also include a flat, fiber attachment surface 514ab for securing the fiber assembly 540 (illustrated in FIG. 5A) to the mounting frame 514. In this non-exclusive implementation, the fiber attachment surface 514ab is generally annular and encircles the recessed region 514aa. However, other designs are possible.

Additionally, FIG. 5C illustrates that the laser assembly 510 can include a driver board 572 having electrical connector 572a that is used to electrically connect the system controller 24 (illustrated in FIG. 1) to the laser assembly 510. In certain implementations, the driver board 572 is unique because it allows for faster rise and fall times because the driver board 572 is so close to lasers. As a result thereof, there is very little inductance and capacitance.

FIGS. 5D and 5E are perspective views of another portion of the laser assembly 510 of FIG. 5A. More specifically, FIGS. 5D and 5E illustrate the laser assembly 510 without the top frame 514a (illustrated in FIGS. 5B and 5C), the beam focuser 544 (illustrated in FIGS. 5B and 5C), and the focuser attachment assembly 546 (illustrated in FIGS. 5B and 5C) removed. Comparing FIGS. 5D and 5E, a mounting bridge 574 is shown in FIG. 5D, but this component has been removed in FIG. 5E.

With reference to FIGS. 5D and 5E, the laser assembly 510 includes (i) the first laser subassembly 516, (ii) the second laser subassembly 518, (iii) the third laser subassembly 520, (iv) the optical assembly 522 having the first prism 522A, the second prism 522B, and the third prism 522C, (v) the transfer assembly 536, and (vii) the intermediate frame 514d that are somewhat similar to the corresponding components described above. However, in this implantation, (i) the laser subassemblies 516, 518, 520 are secured to the bottom frame 514b to form the lower, first assembly level 532; (ii) the optical assembly 522 is secured the intermediate frame 514d to form the upper, second assembly level 534; and (iii) the transfer assembly 536 transfers the subassembly beams (not shown in FIGS. 5D and 5E) from the first assembly level 532 to the second assembly level 534.

It should be noted that in this embodiment, the intermediate frame 514d does not extend across the entire mounting frame 514 and can be called the second floor.

Further, in one embodiment, the second assembly level 534 of the laser assembly 510 includes a beam director assembly 576 which directs the beams (not shown in FIGS. 5D and 5E) exiting the optical assembly 522 in the desired direction. In this implementation, the laser assembly 510 is designed to direct the output beam (not shown in FIGS. 5D and 5E) out the top frame 514a (not shown in FIGS. 5D and 5E) along the Y axis. For example, the beam director assembly 576 can include a turning mirror 576a, and an out of plane mirror 576b that cooperate to direct the output beam out the top frame 514a.

FIG. 5F is a perspective view of yet another portion of the laser assembly of FIG. 5A. More specifically, FIG. 5F illustrates the first assembly level 532 without the second assembly level 534 (illustrated in FIG. 5E). With reference to FIG. 5F, the laser assembly 510 includes the first laser subassembly 516; the second laser subassembly 518; and the third laser subassembly 520 that are secured to the bottom frame 514b; and the transfer assembly 536. These components are similar to the corresponding components described above.

In this design, the first laser subassembly 516 includes (i) a first laser 526a; (ii) a first collimator 526c; (iii) a first beam corrector 526d; (iv) a first polarization rotator 526e; (v) a second laser 526f; (vii) a second collimator 526h; (viii) a second beam corrector 526i; (ix) a first beam combiner 526j; and (x) aa axis beam shifter 526k (e.g. a beam displacer) that cooperate to generate a first assembly beam (not shown in FIG. 5F) along a first subassembly beam axis (not shown in FIG. 5F).

Somewhat similarly, the second laser subassembly 518 includes (i) a third laser 528a; (ii) a third collimator 528c; (iii) a third beam corrector 528d; (iv) a second polarization rotator 528e; (v) a fourth laser 528f; (vii) a fourth collimator 528h; (viii) a fourth beam corrector 528i; (ix) a second beam combiner 528j; and (x) a first beam redirector 528k that cooperate to provide a second subassembly beam (not shown in FIG. 5F) along a second subassembly beam axis (not shown in FIG. 5F).

Further, the third laser subassembly 520 can include (i) a fifth laser 530a; (ii) a fifth collimator 530c; (iii) a fifth beam corrector 530d; and (iv) a second beam redirector 530e that cooperate to provide a third subassembly beam (not shown in FIG. 5F) along a third subassembly beam axis (not shown in FIG. 5F).

FIG. 5G is a cut-away view of the laser assembly 510 taken on line 5G-5G in FIG. 5A. Of particular interest, FIG. 5G illustrates the mounting frame 514, the beam focuser 544, the focuser attachment assembly 546, the fiber assembly 540, and the fiber attachment assembly 542.

In this implementation, the top frame 514a includes an opening that is covered by a widow 514e positioned below the beam focuser 544. This window 514e allows for the mounting frame 514 to be sealed or maintained at a controlled environment.

As provided above in the discussion of FIGS. 5B and 5C, without the fiber assembly 540, and the fiber attachment assembly 542 being installed, the focuser alignment tool 566 (illustrated in FIGS. 5B and 5C) can grip and precisely position the beam focuser 544. With the beam focuser 544 precisely positioned, the focuser attachment assembly 546 can be used to fixedly and accurately secure the beam focuser 544 relative to the mounting frame 514.

Subsequently, a fiber alignment tool 578 (illustrated as a box) can be used to accurately position the inlet facet 540a of the fiber assembly 540 and the fiber attachment assembly 542 relative to the beam focuser 544. Next, the fiber attachment assembly 542 can be used to fixedly secure the relative position between inlet facet 540a to the beam focuser 544. The design of the fiber attachment assembly 542 and the fiber alignment tool 578 and can be varied pursuant to the teachings provided herein.

In one, non-exclusive implementation, the fiber attachment assembly 542 allows for the position of the inlet facet 540a to be moved with multiple (e.g. three, four, five, or six) degrees of freedom relative to the beam focuser 544 by the fiber alignment tool 578, and subsequently fixed relative to the beam focuser 544. With this design, the laser subassemblies 516, 518, 520 (illustrated in FIG. 5G) can be individually or jointly activated, and the position of the inlet facet 540a can be finely adjusted with the fiber alignment tool 578 (and subsequently set) so that the three subassembly beams (not shown in FIG. 5G) enter the inlet facet 540a. For example, the fiber attachment assembly 542 can be designed to allow for the position of the inlet facet 540a to be moved with three degrees of freedom (e.g., along the X, Y and Z axes) relative to the beam focuser 544. In certain designs, the inlet facet 540a is insensitive to movement about the X, Y, and Z axes within a relatively large range.

In one, non-exclusive implementation, the fiber attachment assembly 542 includes a bushing 580 that secures the fiber assembly 540 to the fiber attachment surface 514ab, and an optional dust cover assembly 582 that inhibits dust from entering the area. The design of each component can be varied.

FIG. 5H is an enlarged view of the bushing 580 and a portion of the fiber assembly 540 including the inlet facet 540a.

With reference to FIGS. 5G and 5H, in one non-exclusive implementation, the bushing 580 is a one piece component that can include (i) a lower, annular shaped, bushing flange 580a having a flange engagement surface 580b, and (ii) an upper, annular shaped, bushing housing 580c that defines a housing aperture 580d that receives a portion of the fiber assembly 540.

In one implementation, a first bushing adhesive 584 (illustrated with an asterisk symbol in FIG. 5H) is used to fixedly secure the flange engagement surface 580b to the fiber attachment surface 514ab; and a second bushing adhesive 586 (illustrated with an asterisk symbol in FIG. 5H) positioned in the housing aperture 580d is used to fixedly secure the fiber assembly 540 to the bushing housing 580c. With this design, the fiber alignment tool 578 is used to move (i) the bushing 580 relative to the top frame 514a and the beam focuser 544; and (iii) the inlet facet 540a relative to the bushing 580 and the beam focuser 544 until the inlet facet 540a is accurately positioned at that precise target location in the target plane where the beam focuser 544 is focusing the output beam.

For example, the fiber alignment tool 578 can be designed and used to move and precisely position the inlet facet 540a with multiple (e.g. three, four, five, or six) degrees of freedom relative to the beam focuser 544. In the example of FIGS. 5G, the fiber alignment tool 578 can (i) move and position the bushing 580 (with the inlet facet 540a) along X and Z axes, and about the X and Z axes relative to the beam focuser 544 and the top frame 514a; and (ii) move and position the inlet facet 540a along Y and about the Y axis relative to the beam focuser 544 and the bushing 580.

For example, the fiber alignment tool 578 can include one or more translation stages and goniometers that move and position the inlet facet 540a with six degrees of freedom relative to the beam focuser 544.

After the inlet facet 540a is precisely positioned, (i) the first bushing adhesive 584 can be used to fixedly secure the bushing 580 to the top frame 514a; and (ii) the second bushing adhesive 586 can be used to fixedly secure the fiber assembly 540 to the bushing 580. For example, the adhesives 584, 586 can be an ultra-violet light curable glue and the bushing 580 can be made or a material (e.g. sapphire) that is transparent to ultra-violet light. With this design, after the inlet facet 540a is precisely positioned, ultra-violet light can be directed at the adhesives 584, 586 to cure the adhesives 584, 586 and secure the fiber assembly 540 to the bushing 580, and the bushing 580 to the top frame 514a. Subsequently, the fiber alignment tool 578 can be removed, and the laser assembly 510 can be moved to an oven (not shown) to fully cure the adhesive.

In another implementation, bushing 580 can be made out of another material, such as titanium, and the adhesives 584, 586 can be cured by directing the light (e.g., ultra-violet light) into the gaps at the adhesives 584, 586.

With reference back to FIG. 5G, the dust cover assembly 582 inhibits dust from entering the area around the inlet facet 540a. In the non-exclusive implementation of FIG. 5G, the dust cover assembly 582 includes a lower cover portion 582a that encircles the bushing flange 580a, and an upper cover portion 582b encircles the bushing housing 580c and the proximal end of the fiber assembly 540. However, other designs are possible. For example, the dust cover assembly 582 can be designed without the lower cover portion 582a. In this design, the upper cover portion 582b can be secured to the bushing flange 580a.

FIG. 5I is a perspective view of a portion of the laser assembly 510 of FIG. 5A without the mounting frame 514 (illustrated in FIG. 5A). FIG. 5I illustrates that a flexible routing circuit 588 can be used to route power to the lasers 526a, 526f, 528a, 528f, 530a of the laser subassemblies 516, 518, 520. Additionally, the routing circuit 588 can include one or more laser activation components 590, e.g., electrical contact pads (e.g., pogo-pin probe pads). The contact pads 590 allow for the lasers 526a, 526f, 528a, 528f, 530a to be individually or jointly activated during the alignment process of (i) the laser subassemblies 516, 518, 520, (ii) the beam focuser 544 (illustrated in FIG. 5G), and/or (iii) the fiber assembly 540.

For example, (i) a first electrical connection 592a between a first pair of contact pads 590 may be necessary to close the electrical circuit for the first laser 526a to activate the first laser 526a; (ii) a second electrical connection (not shown) between a second pair of contact pads 590 may be necessary to close the electrical circuit for the second laser 526f to activate the second laser 526f; (iii) a third electrical connection 592c between a third pair of contact pads 590 may be necessary to close the electrical circuit for the third laser 528a to activate the third laser 528a; (iv) a fourth electrical connection 592d between a fourth pair of contact pads 590 may be necessary to close the electrical circuit for the fourth laser 528f to activate the fourth laser 528f; and (v) a fifth electrical connection (not shown) between a fifth pair of contact pads 590 may be necessary to close the electrical circuit for the fifth laser 530a to activate the fifth laser 530a.

It should be noted that the electrical connections 592a, 592c, 592d can be temporary during the initial assembly and alignment process so that the individual lasers 526a, 526f, 528a, 528f, 530a individually activate. Subsequently, after this process is complete, the electrical connections 592a, 592c, 592d can be made permanent.

In the discussion above, the electrical contact pads 590 allow for the individual activation of the lasers 526a, 526f, 528a, 528f, 530a. Alternatively, the contact pads 590 can be can be designed to active more than one of the lasers 526a, 526f, 528a, 528f, 530a concurrently. For example, a pair of contact pads 590 can concurrently activate the first and second lasers 526a, 526f of the first laser subassembly 516. In one non-exclusive implementation, wirebonds are used for permanent connection between certain contact pads 590.

In one implementation, the components of the laser assembly 510 (in any embodiment provided herein) have a low coefficient of thermal expansion (“CTE”), and the coefficient of thermal expansion is matched to further minimize pointing errors due to temperature changes. In alternative non-exclusive examples, each of components of the laser assembly 510 are designed to have a coefficient of thermal expansion of less than six, seven, eight, ten or twelve parts per million/degrees Celsius. Additionally or alternatively, in alternative non-exclusive examples, the components of the laser assembly 510 are designed to have a coefficient of thermal expansion of within 0.2, 0.3, 0.4, or 0.5 parts per million/degrees Celsius. Stated alternatively, each component of the laser assembly 510 is designed to have a coefficient of thermal expansion that is within 2, 3, 4, 5, 6, 7, 8, 9, 10, or 20 percent of the coefficient of thermal expansion of any other component in the laser assembly 510.

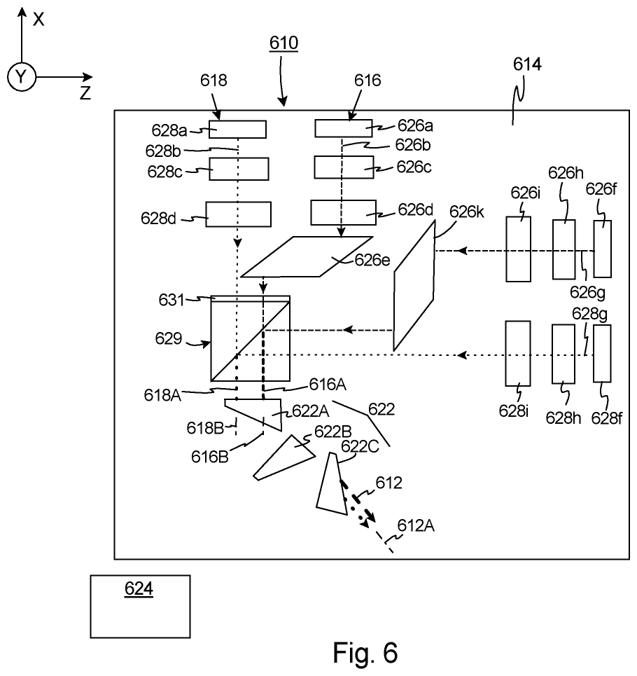

FIG. 6 is simplified top, plan illustration of another implementation of a laser assembly 610 that generates an output beam 612 (illustrated with two thick, solid arrows) along an output axis 612A. In this non-exclusive implementation, the laser assembly 610 includes (i) a mounting frame 614, (ii) a first laser subassembly 616 that generates a collimated, first subassembly beam 616A (illustrated with a dashed arrow); (iii) a second laser subassembly 618 that generates a collimated second subassembly beam 618A (illustrated with dotted arrow); (iv) an optical assembly 622 that receives and compresses/contracts the subassembly beams 616A, 618A to provide the output beam 612; (vi) a polarization rotator 631; (vii) a beam combiner assembly 629; and (viii) a system controller 624 that controls one or more of the components of the laser assembly 610. The design, size, position and/or shape of these components can be varied pursuant to the teachings provided herein. Further, the laser assembly 610 can be designed with more or fewer components than illustrated in FIG. 6, and/or the arrangement of these components can be different than that illustrated in FIG. 6.

Similar to the designs above, the components of the laser assembly 610 are uniquely designed to have a relatively high power, the laser assembly 610 is optically and mechanically stable during temperature cycles and mechanical vibrations, and the laser assembly 610 has a relatively small form factor.

The mounting frame 614 can be similar to the corresponding component described above and illustrated in FIG. 1.

The first laser subassembly 616 can be somewhat similar to the first laser subassembly 16 described above and illustrated in FIG. 1. In one implementation, the first laser subassembly 616 includes (i) a first laser 626a that generates a first laser beam 626b; (ii) a first collimator 626c that collimates the first laser beam 626b; (iii) a first beam corrector 626d; (iv) a first beam shifter 626e (e.g. a beam displacer) that shifts the first laser beam 626b; (v) a second laser 626f that generates a second laser beam 626g; (vi) a second collimator 626h that collimates the second laser beam 626g; (vii) a second beam corrector 626i; and (x) a second beam shifter 626k (e.g. a beam displacer) for shifting the second laser beam 626g. In this implementation, these components can be similar to the corresponding components described above and illustrated in FIG. 1.

It should be noted that the first laser subassembly 616 can be designed with more or fewer components than are illustrated in FIG. 6. For example, the first laser subassembly 616 could be designed without one or more of the beam shifters 626e, 626k.

Moreover, the second laser subassembly 618 can be similar to the second laser subassembly 618 described above and illustrated in FIG. 1. For example, the second laser subassembly 618 can include (i) a third laser 628a that generates a third laser beam 628b; (ii) a third collimator 628c that collimates the third laser beam 628b; (iii) a third beam corrector 628d; (iv) a fourth laser 628f that generates a fourth laser beam 628g; (v) a fourth collimator 628h that collimates the fourth laser beam 628g; and (vi) a fourth beam corrector 628i. In this implementation, these components can be similar to the corresponding components described above and illustrated in FIG. 1.

It should be noted that the second laser subassembly 618 can be designed with more or fewer components than are illustrated in FIG. 6. For example, the second laser subassembly 618 could be designed to include one or more of the beam shifters (not shown).

The polarization rotator 631 rotates the polarization of the first laser beam 626e, and rotates the polarization of the third laser beam 628b. In this design, the polarization rotator 631 can be similar to the polarization rotators 26e, 28e described above in reference to FIG. 1. However, in FIG. 6, a single polarization rotator 631 rotates the polarization of both the first laser beam 626b, and the third laser beam 628b. Alternatively, the single polarization rotator 631 can be replaced with multiple polarization rotators.

In one embodiment, the polarization rotator 631 is a transmissive one-half wave waveplate that changes the polarization of the first laser beam 626b and the third laser beam 628b from a first polarization state to a second polarization state.

The beam combiner assembly 629 (i) combines the first laser beam 626b and the second laser beam 626g to provide a first subassembly beam 616A along a first subassembly beam axis 616B; (ii) combines the third laser beam 628b and the fourth laser beam 628g to provide a second subassembly beam 618A along a second subassembly beam axis 618B. In the non-exclusive implementation of FIG. 6, the second subassembly axis 618B is substantially parallel with the first subassembly axis 616B and the X axis.

The design of the beam combiner assembly 629 can be similar to the first beam combiner 26j and the second beam combiner 28j described above and illustrated in FIG. 1. However, in FIG. 6, a single beam combiner 629 (i) combines the first and second laser beams 626b, 626g; and (ii) combines the third and fourth laser beams 628b, 628g. Alternatively, the single beam combiner 629 can be replaced with multiple beam combiners.

In one, non-exclusive implementation, the beam combiner assembly 629 can be a polarization beam combiner that reflects light at the first polarization state and transmits light at the second polarization state. With this design, (i) the first laser beam 626b is transmitted through the beam combiner assembly 629; and the second laser beam 626g is reflected ninety degrees by the beam combiner assembly 629 to generate the first subassembly beam 616A; and (ii) the third laser beam 628b is transmitted through the beam combiner assembly 629; and the fourth laser beam 628g is reflected ninety degrees by the beam combiner assembly 629 to generate the second subassembly beam 618A.

In the non-exclusive implementation of FIG. 6, each of the subassembly beams 616A, 618A is a cone of energy that is illustrated as a dashed line, that represents the center of the respective subassembly beams 616A, 618A. In alternative, non-exclusive implementations, before the subassembly beams 616A, 618A enter the optical assembly 622, the center of adjacent subassembly beams 616A, 618A are spaced apart at least 0.1, 1, 3, or 10 millimeters. In certain implementations, the beams 616A, 618A are as close as possible to conserve brightness.

It should be noted that although the centers of the subassembly beams 616A, 618A are illustrated as being spaced apart significantly before entry in the optical assembly 622, because each the subassembly beams 616A, 618A is a cone of energy, the subassembly beams 616A, 618A are actually adjacent to each other.

With this design, the output beam 612 is made of the two subassembly beams 616A, 618A compressed together. In alternative, non-exclusive implementations, after the subassembly beams 616A, 618A exit the optical assembly 622, centers of adjacent subassembly beams 616A, 618A are spaced apart at less than 0.1, 0.5, 1, or 2 millimeters.

Moreover, in alternative, non-exclusive implementations, after the subassembly beams 616A, 618A exit the optical assembly 622, the outer beam 612 has a cross-sectional area of less than 0.02 mm\hat{ }2, 1 mm\hat{ }2, 3.5 mm\hat{ }2, 7.0 mm\hat{ }2 or 35 mm\hat{ }2 (millimeters squared).

It should be noted that in certain implementations, (i) the first subassembly beam 616A has both S-polarization and P-polarization; and (ii) the second subassembly beam 618A has both S-polarization and P-polarization.

In the non-exclusive implementation of FIG. 6, the optical assembly 622 and the control system 624 can be similar to the corresponding components described above and illustrated in FIG. 1. For example, the optical assembly 622 can include a plurality of spaced apart prisms, such as a first prism 622A, a second prism 622B, and a third prism 622C that are spaced apart.

It should be noted that the design in FIG. 6 is illustrated as a single level design. Alternatively, for example, the laser assembly of FIG. 6 can be designed as a multi-layer design.

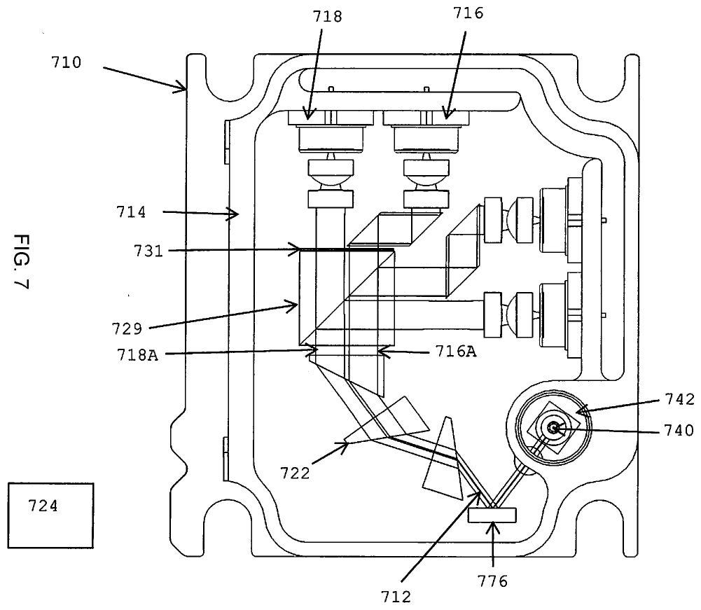

FIG. 7 is simplified top plan illustration of still another implementation of a laser assembly 710 that generates an output beam 712. In this non-exclusive implementation, the laser assembly 710 includes (i) a mounting frame 714; (ii) a first laser subassembly 716 that generates a collimated, first subassembly beam 716A; (iii) a second laser subassembly 718 that generates a collimated second subassembly beam 718A; (iv) an optical assembly 722 that receives and compresses/contracts the subassembly beams 716A, 718A to provide the output beam 712; (v) a polarization rotator 731; (vi) a beam combiner assembly 729; (vii) a system controller 724 that controls one or more of the components of the laser assembly 710; (viii) a beam director assembly 776; and (ix) a fiber attachment assembly 542 for coupling the output beam 712 to a fiber assembly 740. The design, size, position and/or shape of these components can be varied pursuant to the teachings provided herein. Further, the laser assembly 710 can be designed with more or fewer components than illustrated in FIG. 7, and/or the arrangement of these components can be different than that illustrated in FIG. 7.

It should be noted that (i) the mounting frame 714; (ii) the first laser subassembly 716; (iii) the second laser subassembly 718; (iv) the optical assembly 722; (v) the polarization rotator 731; (vi) the beam combiner assembly 729; and (vii) the system controller 724 can be similar to the corresponding components described above and illustrated in FIG. 6. However, in the design of FIG. 7, the laser assembly 710 additionally includes the beam director assembly 776 and the fiber attachment assembly 742. In this embodiment, the beam director assembly 776 and the fiber attachment assembly 742 can be similar to the corresponding components described in reference to FIGS. 5A-5I.

Similar to the designs above, the components of the laser assembly 710 are uniquely designed to have a relatively high power, the laser assembly 710 is optically and mechanically stable during temperature cycles and mechanical vibrations, and the laser assembly 710 has a relatively small form factor.

It should be noted that the design in FIG. 7 is illustrated as a single level design. Alternatively, for example, the laser assembly of FIG. 7 can be designed as a multi-layer design.

While the laser assemblies as shown and disclosed herein are fully capable of obtaining the objects and providing the advantages herein before stated, it is to be understood that it is merely illustrative of the presently preferred embodiments of the invention and that no limitations are intended to the details of construction or design herein shown other than as described in the appended claims.

1. A laser assembly for generating an output beam, the laser assembly comprising:
a first laser that generates a first laser beam;
a second laser that generates a second laser beam;
a third laser that generates a third laser beam;
a fourth laser that generates a fourth laser beam;
a beam combiner assembly that (i) combines the first laser beam and the second laser beam to form a first subassembly beam that is directed along a first subassembly beam axis; and (ii) combines the third laser beam and the fourth laser beam to form a second subassembly beam that is directed along a second subassembly beam axis that is substantially parallel to the first subassembly beam axis; and
an optical assembly is a prism compressor that compresses the subassembly beams to provide the output beam.

2. (canceled)

3. The laser assembly of claim 1 further comprising a fifth laser that generates a third subassembly beam that is directed along a third subassembly beam axis that is substantially parallel to the first subassembly beam axis and the second subassembly beam axis; and wherein the optical assembly compresses the subassembly beams to provide the output beam.

4. (canceled)

5. The laser assembly of claim 1 further comprising a fiber including an inlet facet, a beam focuser that focuses the output beam at the inlet facet so that the output beam is accepted by the inlet facet, and a focuser attachment assembly that allows for the adjustment of the beam focuser with at least three degrees of freedom relative to the optical assembly, and a fiber attachment assembly that allows for the adjustment of the inlet face with at least three degrees of freedom relative to the beam focuser.

6. (canceled)

7. The laser assembly of claim 1 wherein the optical assembly includes a plurality of spaced apart prisms.

8. (canceled)

9. The laser assembly of claim 1 wherein the first laser includes a first collimator that collimates the first laser beam, and a first beam corrector that further collimates and adjusts the pointing of the first laser beam.

10. The laser assembly of claim 1 further comprising (i) a mounting frame including a first frame that retains the lasers to form a first assembly level, and a second frame that retains the optical assembly to form a second assembly level; and (ii) a transfer assembly that transfers the subassembly beams from the first assembly level to the second assembly level.

11. A laser assembly generating an output beam, the laser assembly comprising:
a first assembly level that includes (i) a first laser subassembly that generates a first subassembly beam that is directed along a first subassembly beam axis; and (ii) a second laser subassembly that generates a second subassembly beam that is directed along a second subassembly beam axis that is substantially parallel to the first subassembly beam axis;
a second assembly level that includes an optical assembly that compresses the subassembly beams to provide the output beam, wherein the second assembly level is different from the first assembly level; and
a transfer assembly that transfers the subassembly beams from the laser subassemblies on the first assembly level to the optical assembly on the second assembly level.

12. The laser assembly of claim 11 wherein each laser subassembly includes at least two lasers.

13. (canceled)

14. The laser assembly of claim 11 further comprising a third laser subassembly that generates a third subassembly beam along a third subassembly beam axis that is substantially parallel to the first subassembly beam axis and the second subassembly beam axis; and wherein the optical assembly compresses the subassembly beams to provide the output beam.

15. (canceled)

16. The laser assembly of claim 11 further comprising a fiber including an inlet facet, and a beam focuser that focuses the output beam at the inlet facet so that the output beam is accepted by the inlet facet, and a focuser attachment assembly that allows for the adjustment of the beam focuser with six degrees of freedom relative to the optical assembly, and a fiber attachment assembly that allows for the adjustment of the inlet face with six degrees of freedom relative to the beam focuser.

17. (canceled)

18. The laser assembly of claim 11 wherein the optical assembly includes a plurality of spaced apart prisms that compress the subassembly beams along an axis.

19. The laser assembly of claim 11 wherein the first laser subassembly includes a first laser that generates a first laser beam and a first collimator that collimates the first laser beam, and a first beam corrector that further collimates and adjusts the pointing of the first laser beam.

20. The laser assembly of claim 11 further comprising a mounting frame including a first frame that retains the laser subassemblies to form the first assembly level; and a second frame that retains the optical assembly to form a second assembly level.

21. A laser assembly comprising:
a first laser subassembly that includes (i) a first laser that generates a first laser beam; (ii) a first collimator that collimates the first laser beam, (iii) a first beam corrector that further collimates and adjusts the pointing of the first laser beam; (iv) a second laser that generates a second laser beam; (v) a second collimator that collimates the second laser beam, (vi) a second beam corrector that further collimates and adjusts the pointing of the second laser beam; and (vii) a beam combiner assembly that combines the first laser beam and the second laser beam to form a first subassembly beam that is directed along a first subassembly beam axis.

22. (canceled)

23. The laser assembly of claim 21 further comprising (i) a second laser subassembly that includes: a third laser that generates a third laser beam; a third collimator that collimates the third laser beam; a third beam corrector that further collimates the third laser beam; a fourth laser that generates a fourth laser beam; a fourth collimator that collimates the fourth laser beam; a fourth beam corrector that further collimates the fourth laser beam; and wherein the beam combiner assembly combines the third laser beam and the fourth laser beam to form a second subassembly beam that is directed along a second subassembly beam axis; and (ii) an optical assembly that compresses the subassembly beams to provide an output beam.

24. The laser assembly of claim 23 further comprising a third laser subassembly that generates a third subassembly beam along a third subassembly beam axis that is substantially parallel to the first subassembly beam axis and the second subassembly beam axis; and wherein the optical assembly compresses the subassembly beams to provide the output beam.

25. (canceled)

26. The laser assembly of claim 23 further comprising a fiber including an inlet facet, and a beam focuser that focuses the output beam at the inlet facet so that the output beam is accepted by the inlet facet, and a focuser attachment assembly that allows for the adjustment of the beam focuser with six degrees of freedom relative to the optical assembly, and a fiber attachment assembly that allows for the adjustment of the inlet face with six degrees of freedom relative to the beam focuser.

27. (canceled)

28. The laser assembly of claim 23 wherein the optical assembly includes a plurality of spaced apart prisms.

29. (canceled)

30. The laser assembly of claim 23 further comprising (i) a mounting frame including a first frame that retains the laser subassemblies to form a first assembly level, and a second frame that retains the optical assembly to form a second assembly level; and (ii) a transfer assembly that transfers the subassembly beams from the first assembly level to the second assembly level.

31. (canceled)

32. (canceled)

33. (canceled)

34. A laser assembly for generating an output beam, the laser assembly comprising:
a first laser subassembly that generates a first subassembly beam;
a second laser subassembly that generates a second subassembly beam;
an optical assembly that compresses the subassembly beams to provide the output beam;
a fiber including an inlet facet;
a beam focuser that focuses the output beam at the inlet facet so that output beam is accepted by the inlet facet;
a focuser attachment assembly that allows for the adjustment of the beam focuser with at least three degrees of freedom relative to the optical assembly; and
a fiber attachment assembly that allows for the adjustment of the inlet face with at least three degrees of freedom relative to the beam focuser.

35. The laser assembly of claim 34 wherein the focuser attachment assembly allows for the adjustment of the beam focuser along three orthogonal axes relative to the optical assembly; and wherein the fiber attachment assembly allows for the adjustment of the inlet face along the three orthogonal axes relative to the beam focuser.

36. (canceled)
